(19) United States
(12) Patent Application Publication
(10) Pub. No.: US 2022/0002902 A1
(43) Pub. Date: Jan. 6, 2022

(54) HEAT SHIELD DEVICE FOR INSULATING HEAT AND SMELTING FURNACE

(71) Applicants: Shanghai Institute of Microsystem and Information Technology, Chinese Academy of Sciences, Shanghai (CN); Zing Semiconductor Corporation, Shanghai (CN)

(72) Inventors: Zhongying Xue, Shanghai (CN); Yun Liu, Shanghai (CN); Xing Wei, Shanghai (CN); Zhan Li, Shanghai (CN); Tao Wei, Shanghai (CN); Minghao Li, Shanghai (CN)

(21) Appl. No.: 17/139,942

(22) Filed: Dec. 31, 2020

(30) Foreign Application Priority Data
Jul. 1, 2020 (CN) 202010621665.X

(51) Int. Cl. C30B 15/14; C30B 29/06

(52) U.S. Cl. CPC C30B 15/14; C30B 29/06

(57) ABSTRACT

Disclosed are a heat shield device for insulating heat and a smelting furnace. The heat shield device comprises a heat shield unit and a heat insulation unit. The heat shield unit comprises a shield bottom provided with a through hole, and a shield wall disposed on a side of the shield bottom opposite to the through hole. The heat insulation unit comprises a heat insulation part disposed above a layer plate of the shield bottom close to a liquid level of a crucible and a heat preservation part. The smelting furnace used for growth of monocrystalline silicon comprises the heat shield device, a crucible and a heater. The heat shield device of the present invention can increase a temperature gradient between the heat shield unit and the crucible, thereby facilitating rapid formation of silicon crystal bar and improving production efficiency of the silicon crystal bar.

### CROSS REFERENCE TO RELATED APPLICATIONS

The present application claims the benefit of Chinese Patent Application No. 202010621665.X filed on Jul. 1, 2020, the contents of which are incorporated herein by reference in their entirety.

### TECHNICAL FIELD

The present invention relates to the field of manufacturing of semiconductors, and in particular to a heat shield device for insulating heat and a smelting furnace.

### BACKGROUND

Monocrystalline silicon is a raw material for manufacturing semiconductor silicon devices, and used to manufacture high-power rectifiers, high-power transistors, diodes, switching devices, etc. As molten elemental silicon is cooled, silicon atoms are arranged in a diamond lattice into many crystal nuclei. If these crystal nuclei are grown into crystal grains with the same crystallographic orientation, these crystal grains will combine in parallel and crystallize into monocrystalline silicon. A production method of the monocrystalline silicon usually comprises producing polycrystalline silicon or amorphous silicon first, and then growing rod-shaped monocrystalline silicon from melt by using the Czochralski method or the zone melting method.

Single crystal furnaces are a kind of equipment in which polycrystalline silicon and other polycrystalline materials are melted by a graphite heater in inert gas (mainly nitrogen, or helium) environment, and dislocation-free single crystal are grown through the Czochralski method.

At present, large-size silicon single crystals, especially silicon single crystals with sizes of 12 inches or larger, are mainly prepared through the Czochralski method. The Czochralski method involves melting high-purity polycrystalline silicon of 99.999999999% (eleven nines) in a quartz crucible, and preparing silicon single crystal by subjecting seed crystals to seeding, shouldering, isometric growth, and finishing. The heat field formed by graphite and a heat insulation material is of the most critical in this method, and the design of the heat field directly determines the quality, process, and energy consumption of the crystal.

In the entire design of the heat field, the most critical is the design of the heat shield. Firstly, the design of the heat shield directly affects the vertical temperature gradient of the solid-liquid interface, and determines the crystal quality by influencing a V/G ratio with changed temperatures. Secondly, the design of the heat shield will influence the horizontal temperature gradient of the solid-liquid interface, and control the quality uniformity of the entire silicon wafer. Finally, a properly designed heat shield will influence the heat history of the crystal, and control nucleation and growth of defects inside the crystal. Therefore, the design of the heat shield is very critical in the process of preparing high-grade silicon wafers.

At present, an outer layer of a commonly used heat shield is a SiC coating layer or pyrolytic graphite, and an inner layer the commonly used heat shield is heat insulation graphite felt. The heat shield which is cylindric is positioned in an upper portion of the heat field. A crystal bar is pulled out of the cylindric heat shield. The graphite of the heat shield which is close to the crystal bar has lower heat reflectivity and absorbs heat emitted from the crystal bar. The graphite on the outside surface of the heat shield usually has higher heat reflectivity, which is beneficial to reflect back the heat emitted from the melt, thereby improving the heat insulation performance of the heat field and reducing power consumption of the whole process.

The heat insulation graphite felt inside the existing heat shield absorbs heat, such that the temperature at the side of the heat shield close to the crystal bar is relatively high, and thus the temperature gradient between the heat shield and the solid-liquid interface is relatively small. The temperature gradient directly affects the pulling rate for the Czochralski method, resulting in a low pulling rate for the Czochralski method, a low crystal bar-forming rate and a low production rate.

Therefore, the above technical problems need to be solved by those skilled in the art.

### SUMMARY

In view of the abovementioned problems in the prior art, an objective of the present invention is to provide a heat shield device for insulating heat, which can ensure temperature uniformity of various areas in a smelting furnace, thereby avoiding non-uniform temperatures from influencing baking quality of a wafer.

In order to solve the above problems, a heat shield device for insulating heat is provided in the present invention, which comprises a heat shield unit and a heat insulation unit.

The heat shield unit comprises a shield bottom provided with a through hole at a center thereof for passing melt to be pulled through, and a shield wall disposed on a side of the shield bottom opposite to the through hole. The shield bottom has a double layer structure in which an accommodation cavity is provided, and the accommodation cavity has a height not less than a preset height.

The heat insulation unit is disposed inside the accommodation cavity and comprises a heat insulation part disposed above a layer plate of the shield bottom close to a liquid level of a crucible and a heat preservation part. A distance between the heat insulation part and the layer plate of the shield bottom close to the liquid level of the crucible is not larger than a preset distance. The heat insulation part is used to completely prevent heat of the crucible from dispersing into the heat shield device for insulating heat. An interior of the accommodation cavity is filled with the heat preservation part, in addition to the heat insulation part.

In a preferred embodiment, the shield bottom comprises a first layer plate, a second layer plate and a lateral plate, which enclose the through hole.

In a preferred embodiment, the first layer plate, the second layer plate, the lateral plate and the shield wall enclose the accommodation cavity.

In a preferred embodiment, the first layer plate is close to the crucible, and the second layer plate is away from the crucible

In a preferred embodiment, the second layer plate is tilted in a direction towards the shield wall at a tilt angle in a range from 1° to 10°.

In a preferred embodiment, the preset height is in a range from 30 mm to 50 mm.

In a preferred embodiment, the preset distance is in a range from 0 mm to 50 mm.

In a preferred embodiment, the shield wall has a single layer structure, in which one end of the single layer structure is connected with the first layer plate, and the other end of the single layer structure is connected with an inner wall of a furnace body.

In a preferred embodiment, the shield wall has a double layer structure, in which one end of the double layer structure is respectively connected with the first layer plate and the second layer plate, and the other end of the double layer structure is connected with an inner wall of a furnace body; and an interior of the double layer structure is filled with the heat preservation part.

A smelting furnace for growth of monocrystalline silicon is also provided in the present invention. The smelting furnace for growth of monocrystalline silicon comprises a heat shield device as described above, a crucible, and a heater. The smelting furnace has a cavity in which the crucible for containing melt is disposed, and the heater is disposed outside the crucible for heating monocrystalline silicon melt in the crucible. The heat shield device is disposed above a port of the crucible, and movement of the heat shield device causes the growth of monocrystalline silicon crystal.

By adopting the aforementioned technical solutions, the present invention has the following beneficial effects:

In the heat shield device and the smelting furnace of the present invention, a heat insulation plate is disposed in the heat shield device to prevent heat of the crucible from dispersing to a crystal bar, thereby increasing the temperature gradient between the heat shield and the crucible. The larger the temperature gradient is, the higher the pulling rate is, which facilitates rapid formation of the silicon crystal bar and improves production efficiency of the silicon crystal bar.

### BRIEF DESCRIPTION OF DRAWINGS

In order to more clearly illustrate the technical solutions of the present invention, the drawings that are used in the description of the embodiments or the prior art will be briefly introduced hereafter. Obviously, the drawings in the following description are only some embodiments of the present invention, and other drawings can be obtained based on these drawings by those of ordinary skill in the art without creative work.

FIG. 1 is a schematic structural diagram of a heat shield device according to Embodiment 1 of the present invention;

FIG. 2 is a schematic structural diagram of a shield bottom according to Embodiment 1 of the present invention;

FIG. 3 is a schematic structural diagram of a heat insulation part according to an embodiment of the present invention;

FIG. 4 is a schematic structural diagram of a heat insulation part according to another embodiment of the present invention; and

FIG. 5 is a schematic structural diagram of a heat shield device and a smelting furnace according to Embodiment 2 of the present invention.

In the drawings: 1—heat shield unit, 11—shield bottom, 12—shield wall, 111—through hole, 112—accommodation cavity, 113—first layer plate, 114—second layer plate, 115—lateral plate, 2—heat insulation unit, 21—heat insulation part, 22—heat preservation part, 3—crucible, 4—heater, and 5—shaft.

### DETAILED DESCRIPTION

Hereafter, the technical solutions according to embodiments of the present invention will be described clearly and thoroughly with reference to drawings. Obviously, the described embodiments are only part of, not all of, the embodiments of the present invention. Based on the embodiments of the present invention, all other embodiments obtained by those of ordinary skill in the art without any creative work shall fall within the protection scope of the present invention.

The term “an embodiment” or “embodiments” herein means that it can encompass particular features, structures or characteristics in at least one implementation of the present invention. In the description of the present invention, it should be understand that the terms “up”, “down”, “left”, “right”, “top”, “bottom”, and the like, refer to a direction or position relationship with respect to the direction or position relationship as shown in the drawing. They are only used for the convenience of describing the present invention and simplifying the description, but do not imply that the referred device or element must have a particular direction or must be constructed and operated in a particular direction or position. Therefore, they cannot be construed as limiting the present invention. In addition, the terms “first” and “second” are only used for the purpose of description, but cannot be construed as indicating or suggesting relative importance, or implying the amount of the referred technical features. Thus, a feature defined with “first” or “second” may clearly or impliedly comprise one or more of such features. Furthermore, the terms “first”, “second”, or the like are used to distinguish similar objects, and are not intended to define a particular order or a sequential order. It should be understood that data used with reference to the terms may be interchanged, where appropriate, so that the embodiments of the present invention described herein can be implemented in an order other than those illustrated or described herein.

Embodiment 1

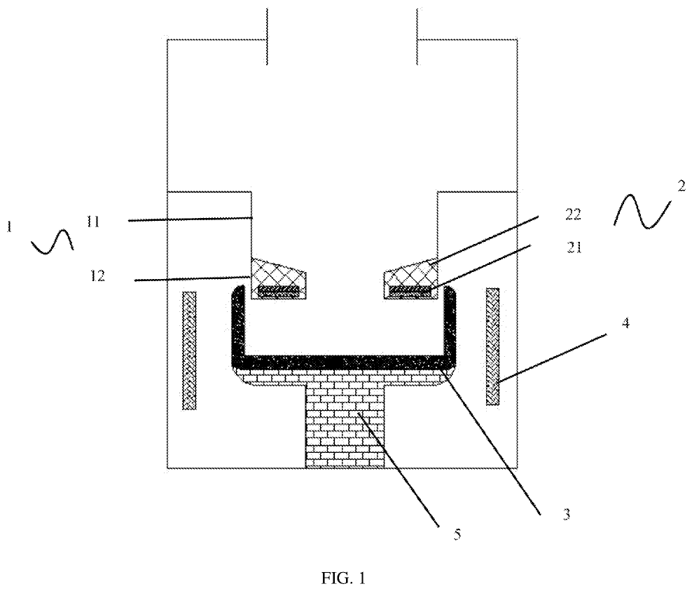

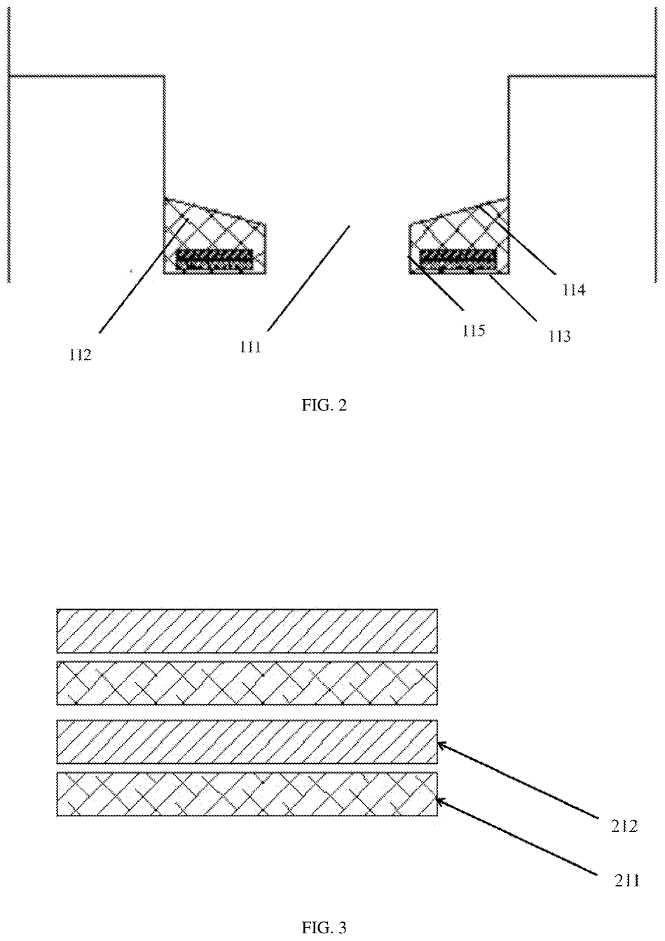

A heat shield device for insulating heat is provided in Embodiment 1. Refer to FIGS. 1 and 2. The heat shield device for insulating heat comprises a heat shield unit 1 and a heat insulation unit 2.

The heat shield unit 1 comprises a shield bottom 11 provided with a through hole 111 at a center thereof for passing melt to be pulled through, and a shield wall 12 disposed on a side of the shield bottom 11 opposite to the through hole 111. The shield bottom 11 has a double layer structure in which an accommodation cavity 112 is provided, and the accommodation cavity 112 has a height not less than a preset height.

The heat insulation unit 2 is disposed inside the accommodation cavity 112 and comprises a heat insulation part 21 disposed above a layer plate of the shield bottom 11 close to a liquid level of a crucible and a heat preservation part 22. A distance between the heat insulation part 21 and the layer plate of the shield bottom 11 close to the liquid level of the crucible is not larger than a preset distance. The heat insulation part 21 is used to completely prevent heat of the crucible from dispersing into the heat shield device for insulating heat. An interior of the accommodation cavity 112 is filled with the heat preservation part 22, in addition to the heat insulation part 21.

In particular, the shield bottom 11 comprises a first layer plate 113, a second layer plate 114 and a lateral plate 115, which enclose the through hole 111.

Further, the first layer plate 113 is close to the crucible and is disposed in parallel to a port of the crucible. The second layer plate 114 is away from the crucible.

Further, the second layer plate 114 is tilted in a direction towards the shield wall 12 at a tilt angle in a range from 1° to 10°. Preferably, the second layer plate 114 is tilted at a tilt angle of 5°, and an end of the second layer plate 113 connected with the lateral plate is lower than an end of the second layer plate 114 connected with the shield wall 12.

In particular, the preset height is in a range from 30 mm to 50 mm to ensure that there can be a sufficient space for placing the heat insulation part.

In particular, the preset distance is in a range from 0 mm to 50 mm. Preferably, the preset distance is 25 mm. If the heat insulation part 21 is completely attached to the first layer plate 113, although heat can be completely isolated, the temperature gradient may be too large and the pulling rate may be too high, such that the monocrystalline silicon bar is produced too fast, thereby resulting in defects. If the distance between the heat insulation part 21 and the first layer plate 113 is too large, a portion of heat might be absorbed by the heat shield unit 1, and the temperature gradient might be slightly increased, which cannot bring better effects for the pulling rate and the production of the monocrystalline silicon bar.

In particular, the shield wall 12 has a single layer structure, in which one end of the single layer structure is connected with the first layer plate 113, and the other end of the single layer structure is connected with an inner wall of a furnace body.

In particular, the heat insulation part 21 is a heat insulation plate comprising a plurality of heat insulation film assemblies.

Further, as shown in FIG. 3, the heat insulation plate comprises at least two heat insulation film assemblies. The heat insulation film assembly comprises a first refractive layer 211 having first refractivity and a second refractive layer 212 having second refractivity which is different from the first refractivity.

Further, the first refractive layer 211 is made of silicon or molybdenum, and the second refractive layer 212 is made of quartz.

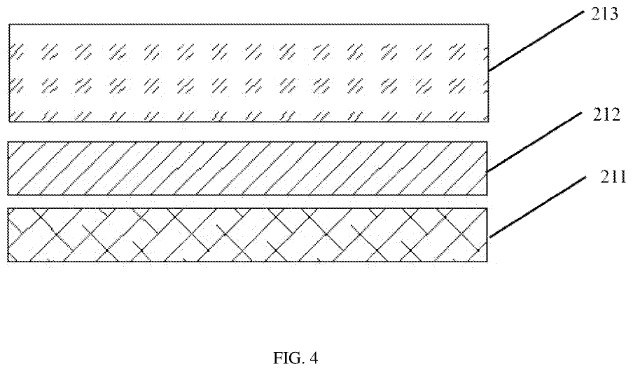

In some embodiments, as shown in FIG. 4, the heat insulation plate at least comprises a supporting layer 213 and one heat insulation film assembly. The heat insulation film assembly comprises a first refractive layer 211 having first refractivity and a second refractive layer 212 having second refractivity which is different from the first refractivity. The supporting layer 213, the first refractive layer 211 and the second refractive layer 212 are attached and connected in sequence.

Further, the first refractive layer 211 is made of silicon, the second refractive layer 212 is made of quartz or silicon nitride, and the supporting layer 213 is made of silicon.

In particular, the heat preservation part 22 has a porous structure made of a heat preservation material, and the heat preservation material is graphite.

A smelting furnace for growth of monocrystalline silicon crystal is also provided in Embodiment 1, which comprises any one of the heat shield devices as described above, a crucible 3, and a heater 4. The smelting furnace has a cavity in which the crucible 3 for containing melt is disposed. The heater 4 is disposed outside the crucible 3 for heating monocrystalline silicon melt in the crucible 3. The heat shield device is disposed above a port of the crucible 3, and movement of the heat shield device causes the growth of monocrystalline silicon crystal.

In particular, the crucible 3 is a quartz crucible, which is resistant to high temperatures and may be used for containing silicon melt in a molten state. The crucible 3 is supported by a shaft 5. The shaft 5 rotates the crucible 3 to improve heating uniformity of the silicon melt in the crucible 3.

Further, the heater 4 is disposed in the cavity and around the crucible 3 for providing a heat field of the crucible 3.

Further, the heater 4 may be configured as a ring form to surround the crucible 3 so as to improve uniformity of the heat field.

In particular, a method for growing monocrystalline silicon comprises the following steps: adding a raw material into the crucible 3; heating the crucible 3 with the heater 4 to transform the raw material in the crucible 3 to melt in a molten state; and transferring heat generated by the crucible 3 to the heat shield device in which the heat shield unit 1 absorbs the heat, wherein the heat absorbed is isolated from a silicon crystal bar by the heat insulation plate 21, such that the temperature gradient during the growth of monocrystalline silicon is large, thereby facilitating to increase a puling rate for the growth of monocrystalline silicon.

Embodiment 2

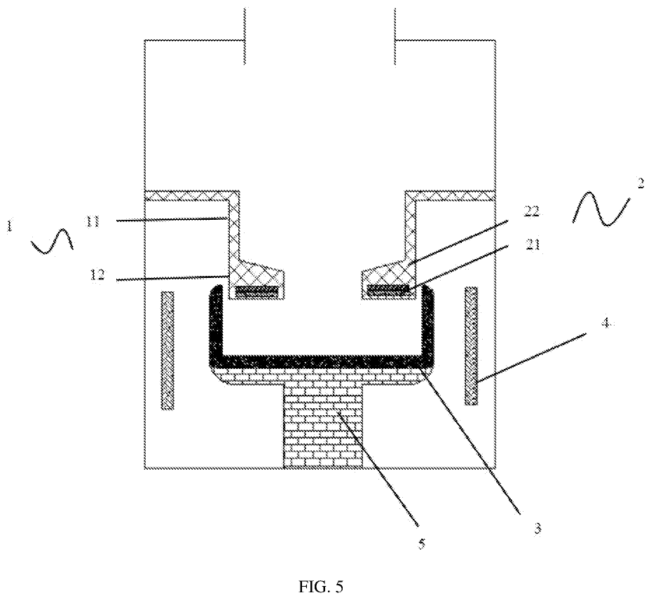

The heat shield device for insulating heat and the smelting furnace provided in Embodiment 2 differ from that of Embodiment 1 in that the shield wall 12 has a double layer structure, in which one end of the double layer structure is respectively connected with the first layer plate 113 and the second layer plate 114, the other end of the double layer structure is connected with an inner wall of a furnace body, and an interior of the double layer structure is filled with the heat preservation part 22, as shown in FIG. 5.

In addition, other parts in Embodiment 2 are the same as that in Embodiment 1, and will not be reiterated here.

In the heat shield device and the smelting furnace provided in Embodiment 2, the shield wall which has a double layer structure can further absorb heat to preserve the temperature. On the other hand, the shield wall with a double layer structure is sturdier than a shield wall with a single layer structure, thereby avoiding vulnerability due to year-round high temperature.

Embodiment 3

The heat shield device for insulating heat and the smelting furnace provided in Embodiment 3 differ from that of Embodiment 1 in that the first layer plate 113 can be prepared from a composite heat insulation material.

The first layer plate 113 at least comprises two heat insulation film assemblies. The heat insulation film assembly comprises a first refractive layer having first refractivity and a second refractive layer having second refractivity which is different from the first refractivity.

Further, the first refractive layer is made of silicon or molybdenum, and the second refractive layer is made of quartz.

In some embodiments, the first layer plate 113 at least comprises a supporting layer and one heat insulation film assembly. The heat insulation film assembly comprises a first refractive layer having first refractivity and a second refractive layer having second refractivity which is different from the first refractivity. The supporting layer, the first refractive layer and the second refractive layer are attached and connected in sequence.

Further, the first refractive layer is made of silicon, the second refractive layer is made of quartz or silicon nitride, and the supporting layer is made of silicon.

In addition, other parts in the Embodiment 3 are the same as those in Embodiment I, and will not be reiterated herein.

The heat shield device for insulating heat and the smelting furnace provided in Embodiment 3, most of heat of the crucible can be isolated by the first layer plate 113, and the remaining heat entering the heat shield device can be isolated by the heat insulation part 21, thereby achieving complete heat insulation. Thus, the temperature gradient can be increased, and the pulling rate can be greatly improved, resulting in rapid growth of the monocrystalline silicon bar, reduced production costs and improved production efficiency.

The above description has already sufficiently disclosed particular embodiments of the present invention. It should be noted that any modification on the particular embodiments made by those skilled in the art does not depart from the scope of the claims of the present invention. Accordingly, the scope of the claims of the present invention is not merely limited to the aforementioned particular embodiments.

1. A heat shield device for insulating heat, wherein the heat shield device comprises a heat shield unit (1) and a heat insulation unit (2);
the heat shield unit (1) comprises a shield bottom (11) provided with a through hole (111) at a center for passing melt to be pulled through, and a shield wall (12) disposed on a side of the shield bottom (11) opposite to the through hole (111); the shield bottom (11) has a double layer structure in which an accommodation cavity (112) is provided, and the accommodation cavity (112) has a height not less than a preset height; and
the heat insulation unit (2) is disposed inside the accommodation cavity (112) and comprises a heat insulation part (21) disposed above a layer plate of the shield bottom (11) close to a liquid level of a crucible and a heat preservation part (22); a distance between the heat insulation part (21) and the layer plate of the shield bottom (11) close to the liquid level of the crucible is not larger than a preset distance; the heat insulation part (21) is used to completely prevent heat of the crucible from dispersing into the heat shield device for insulating heat; and in addition to the heat insulation part (21), the accommodation cavity (112) is filled with the heat preservation part (22).

2. The heat shield device for insulating heat according to claim 1, wherein the shield bottom (11) comprises a first layer plate (113), a second layer plate (114) and a lateral plate (115), which enclose the through hole (111).

3. The heat shield device for insulating heat according to claim 2, wherein the first layer plate (113), the second layer plate (114), the lateral plate (115) and the shield wall (12) enclose the accommodation cavity (112).

4. The heat shield device for insulating heat according to claim 3, wherein the first layer plate (113) is close to the crucible, and the second layer plate (114) is away from the crucible.

5. The heat shield device for insulating heat according to claim 4, wherein the second layer plate (114) is tilted in a direction towards the shield wall (12) at a tilt angle in a range from 1° to 10°.

6. The heat shield device for insulating heat according to claim 1, wherein the preset height is in a range from 30 mm to 50 mm.

7. The heat shield device for insulating heat according to claim 1, wherein the preset distance is in a range from 0 mm to 50 mm.

8. The heat shield device for insulating heat according to claim 1, wherein the shield wall (12) has a single layer structure, in which one end of the single layer structure is connected with the first layer plate (113), and the other end of the single layer structure is connected with an inner wall of a furnace body.

9. The heat shield for insulating heat device according to claim 1, wherein the shield wall (12) has a double layer structure, in which one end of the double layer structure is respectively connected with the first layer plate (113) and the second layer plate (114), and the other end of the double layer structure is connected with an inner wall of a furnace body; and an interior of the double layer structure is filled with the heat preservation part (22).

10. A smelting furnace for growth of monocrystalline silicon, wherein the smelting furnace comprises a heat shield device according to claim 1, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

11. A smelting furnace for growth of monocrystalline silicon, wherein the smelting furnace comprises a heat shield device according to claim 2, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

12. A smelting furnace for growth of monocrystalline silicon, wherein the smelting furnace comprises a heat shield device according to claim 3, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

13. A smelting furnace for growth of monocrystalline silicon, wherein the smelting furnace comprises a heat shield device according to claim 4, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

14. A smelting furnace for growth of monocrystalline silicon, wherein the smelting furnace comprises a heat shield device according to claim 5, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

15. A smelting furnace for growth of monocrystalline silicon, wherein the smelting furnace comprises a heat shield device according to claim 6, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

16. A smelting furnace for growth of monocrystalline silicon, wherein the smelting furnace comprises a heat shield device according to claim 7, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

17. A smelting furnace for growth of monocrystalline silicon, wherein the smelting furnace comprises a heat shield device according to claim 8, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.

18. A smelting furnace for growth of monocrystalline silicon, wherein the smelting furnace comprises a heat shield device according to claim 9, a crucible, and a heater; the smelting furnace has a cavity in which the crucible for containing melt is disposed, the heater is disposed outside the crucible for heating monocrystalline silicon melt in the crucible; and the heat shield device is disposed above a port of the crucible, and movement of the heat shield device causes the growth of monocrystalline silicon.
